(19) United States
(12) Patent Application Publication
(10) Pub. No.: US 2007/0109831 A1
(43) Pub. Date: May 17, 2007

(54) Semiconductor product and method for forming a semiconductor product

(76) Inventor: Siva RaghuRam, Germering (DE)

Correspondence Address: SLATER & MATSIL LLP, 17950 PRESTON ROAD, SUITE 1000, DALLAS, TX, 75252, US

(21) Appl. No.: 11/274,485

(22) Filed: Nov. 15, 2005

(51) Int. Cl. G11C 5/06

(52) U.S. Cl. 365/63

(57) ABSTRACT

A semiconductor product includes a first semiconductor chip that includes input/output circuitry enabling transfer of data from memory banks of the semiconductor product to an external electronic device and/or from an external electronic device to the memory banks of the semiconductor product. A number of second semiconductor chips are stacked on and electrically coupled to the first semiconductor chip. The second semiconductor chips are stacked on one another. Each second semiconductor chip of the plurality of second semiconductor chips comprises at least one of the memory banks of the semiconductor product. The memory banks of the second semiconductor chips are accessible by the input/output circuitry arranged on the first semiconductor chip.

### TECHNICAL FIELD

The present invention relates generally to a semiconductor product and method for forming a semiconductor product.

### BACKGROUND

The invention refers to a semiconductor product and to methods for forming a semiconductor product. Semiconductor products like memory products, in particular volatile memory products, comprise a memory array having a plurality of memory cells. In DRAMs (dynamical random access memories), for instance, memory cells accessible by read operations and write operations are provided in the memory array. The memory cells are arranged in rows and columns and are connected to wordlines and bitlines.

Modern memory products comprise rather complex array architectures in which the memory array comprises a plurality of memory banks, the memory banks each comprising a respective plurality of memory cells and all memory banks being accessible in parallel to one another. For accessing the memory banks of the memory array, input/output circuitry is provided that enables performing read operations and/or write operations for programming, deleting or reading of the memory cells. More important, the input/output circuitry enables transfer of data from the memory banks of the semiconductor product to an external electronic device and/or from an external electronic device to the memory banks of the semiconductor product.

In DRAMs, for instance, the input/output circuitry is arranged in a centered chip region called ‘spine’. The spine region containing the input/output circuitry may, for instance, extend between two opposed edges of the semiconductor chip and may be allocated in a centered position with respect the respective other two opposed edges of the DRAM chip. A plurality of, for instance, four memory banks, may be arranged on the semiconductor chip, each memory bank being arranged in one quadrant of the semiconductor chip. Accordingly, the plurality of memory banks is accessible via the input/output circuitry arranged on the same semiconductor chip besides or between the plural memory banks.

In modern manufacture of semiconductor products like DRAMs, the storage capacity, that is the number of information storable in the semiconductor product, steadily increases due to progresses in shrinking of the microelectronic devices and of enlarging the size of the memory chips. However, the potential of shrinking microelectronic elements in semiconductor devices is limited to a certain extent, depending on a respective technology (typically addressed by the respective size of the gate length) and the size of a semiconductor wafer. With increasing wafer diameter the risk of misalignments and other critical parameters in semiconductor manufacturer increases. Furthermore, when a memory product like a DRAM is to be mounted on a motherboard, on a printed circuit board, on a memory module or on another electric device, small lateral dimensions are preferred in order to arrange a large number of memory products on the respective electronic device. However, with small lateral dimensions of semiconductor chips, new techniques of increasing the storage capacity of the memory devices are required.

In conventional stacked devices where respective contacts of plural semiconductor chips are directly connected to one another for accessing the plural devices in which respective contacts of plural semiconductor chips in parallel, the clock frequency for operating the semiconductor chips must be reduced due to the increased capacitance of the input/output contacts connected to one another. If the clock frequency is not reduced, the parasitic influences at the external contacts of the stacked semiconductor chips become too large for safe operation.

### SUMMARY OF THE INVENTION

In one aspect, the invention provides a semiconductor product having an increased storage capacity, that is, which comprises an increased number of memory cells and which is capable of storing an increased number of bits compared to prior art semiconductor products of equal lateral dimensions. In a further aspect, the present invention provides a semiconductor product enabling operating a memory array having an increased number of memory cells without any increase of the load capacitance and parasitic electrical influences for inputting and outputting information to and from the memory chips. In a further aspect, the present invention provides a semiconductor product comprising memory banks each comprising a significantly increased number of memory cells and thus being able to store a significantly increased number of bit information. The semiconductor product according to various embodiments should be operable at higher frequencies than conventional memory chips without the need to reduce the clock frequency.

In a first embodiment, a semiconductor product includes a first semiconductor chip and a plurality of second semiconductor chips. The second semiconductor chips are stacked on one another and the plurality of second semiconductor chips are stacked on the first semiconductor chip. The semiconductor product includes a plurality of memory banks, each memory bank including a plurality of memory cells. The semiconductor product further includes input/output circuitry that enables access of the memory banks by read and write operations. The first semiconductor chip is electrically connected to each of the second semiconductor chips. The first semiconductor chip includes input/output circuitry that enables transfer of data from the memory banks of the semiconductor product to an external electronic device and/or from an external electronic device to the memory banks of the semiconductor product. Each second semiconductor chip of the plurality of second semiconductor chips includes at least one respective memory bank. The memory banks of each second semiconductor chip are accessible by the input/output circuitry arranged on the first semiconductor chip supporting the plurality of second semiconductor chips.

According to embodiments of the invention, a semiconductor product includes a plurality of semiconductor chips stacked on one another, each semiconductor chip comprising at least one memory bank. These semiconductor chips hereinafter are referred to as second semiconductor chips since they are supported by another, first semiconductor chip, the first semiconductor chip comprising the input/output circuitry. Accordingly, whereas in prior art semiconductor products all memory banks as well as the input/output circuitry are integrated on one single semiconductor chip, that is on a single die of semiconductor material, according to embodiments of the invention, each memory bank is arranged on a separate (second) semiconductor chip and the input/output circuitry is arranged on yet another, separated (first) semiconductor chip. Accordingly, whereas in prior art semiconductor products mainly the shrinkage of microelectronic structures and the lateral dimensions of the individual chips are improved, according to embodiments of the invention, the memory banks and the input/output circuitry (required for transferring data from the memory banks of the semiconductor product to an external electronic device and/or from an external electronic device to the memory banks of the semiconductor product) are arranged on separate semiconductor chips that are stacked on one another.

Furthermore, in contrast to conventional stacked chip arrangements in which each chip includes both the respective plural memory banks and the input/output circuitry of a DRAM, according to embodiments of the invention, each (second) semiconductor chip comprises at least one memory bank that may have a twofold, fourfold or yet higher size compared to memory banks of conventional semiconductor chips of equal substrate size. Accordingly, an essentially increased number of memory cells is obtained per memory bank since the memory banks each may cover almost the complete surface area of the main surface of the respective semiconductor chip. Accordingly the single memory bank covering nearly the whole main surface in particular may cover those portions of the main surface that conventionally are occupied by the other memory banks and by the spine region containing the input/output circuitry. According to embodiments of the invention, however, the input/output circuitry and the other memory banks are arranged on the other ones of the stacked semiconductor chips.

The input/output circuitry may comprise, for instance, off-chip drivers (for transferring data from the memory banks of the semiconductor product to an external device), receivers (for transferring data from an external device to the memory banks of the semiconductor product), regulators, as well as any other input/output circuitry devices usually arranged in the spine region of a conventional DRAM chip. The input/output circuitry may generally comprise input drivers (like receivers, for instance) and output drivers (like off-chip drivers), or data input buffers and data output buffers, respectively.

Furthermore, compared to conventional stacked semiconductor products comprising plural semiconductor chips (like DRAMs) having a higher load capacitance and higher parasitic electrical influences when inputting and/or outputting bit information, for inputting and/or outputting bit information to and/or from semiconductor product according to embodiments of the invention, the magnitude of parasitic electrical influences and the load of the exterior electrical contacts (like their capacitance, for instance) are reduced due to the circumstance that the electrical contacts of the individual (second) semiconductor chips stacked on one another are electrically separated from external electrical contacts of the first semiconductor chip (or of an additional support substrate). Since these external contacts of the first semiconductor chip or of the support substrate are used for connecting the semiconductor product according to embodiments of the present invention to another electronic device, like a memory module for instance, only the capacitive load of these exterior contacts (like solder balls of a support substrate or of the first semiconductor chip, for instance) is relevant but not the capacitive load of the contacts of the individual semiconductor chips operated in parallel.

Each second semiconductor chip may comprise at least one memory bank, for instance one, two, three, four or eight memory banks, for instance. In particular, in case of a small number of memory banks per second semiconductor chip, the storage capacity of each second semiconductor chip is increased. At the same time, the capacitive load and the parasitic influences of the second semiconductor chips are reduced compared to semiconductor chips stacked on one another in a conventional stacked device. Thereby inputting and outputting information in and from the semiconductor product according to embodiments of the invention is improved and the semiconductor product according to embodiments of the invention as a consequence is operable at an increased clock frequency compared to prior art. In particular, each second semiconductor chip of the semiconductor product according to embodiments of the invention may be operated at the same clock frequency as operated in a conventional, non-stacked device. Even in case that the clock frequency of the second semiconductor chips would be reduced to some extent, the amount of reduction could be chosen rather small compared to reduced clock frequencies of semiconductor chips stacked in conventional manner.

Furthermore, since the first semiconductor chip and the second semiconductor chips are stacked on one another, the total storage capacity of the semiconductor product is increased without the need to increase the lateral dimensions thereof. Accordingly the number of semiconductor products mountable on an external device (like a motherboard or a memory module etc.) need not be reduced.

Preferably, each second semiconductor chip includes a main surface, the main surfaces of the second semiconductor chips having the same size, and each memory bank of a respective semiconductor chip covers a surface portion substantially corresponding to the size of the respective second semiconductor chip.

Accordingly, each memory bank arranged on a respective separate second semiconductor chip may cover nearly the full surface area of its main surface (for instance of its upper main surface) and may substantially extend to all four edges of the main surface. Since no extra surface area needs to be provided for the other memory banks and for the input/output circuitry on the same respective second semiconductor chip, the size of each memory bank (and the number of its memory cells) may be increased by a factor of at least four.

According to one preferred embodiment, the memory bank of each respective second semiconductor chip essentially covers the full main surface of the respective second semiconductor chip. This means that exactly one memory bank per second semiconductor chip is provided and the number of second semiconductor chips of the semiconductor product according to embodiments of the invention corresponds to the number of memory banks of the semiconductor product. Preferably, all second semiconductor chips are of equal size and of equal lateral dimensions so that they can easily be stacked on one another.

Alternatively, each second semiconductor chip may comprise more than one memory bank, for instance two, three, four or eight memory banks, preferably the same number of memory banks being provided on each second semiconductor chip.

Preferably, the size of the portion of the main surface covered with the memory bank of the respective second semiconductor chip is at least 85%, preferably at least 90% and more preferably at least 95% of the size of the main surface of the respective second semiconductor chip. In the remaining small portions of the main surface, electrical contacts like bond pads or other contacts to be connected, by electrically conductive connecting means, to the first chip may be provided. These remaining small portions of the main surface of the respective second semiconductor chip, which are not occupied with the memory bank, may be provided at edges of the respective second semiconductor chip, for instance.

Preferably, the semiconductor product comprises electrically conductive connecting means providing electrical connection between the first semiconductor chip and each of the second semiconductor chips. The electrically conductive connecting means serve to electrically connect each of the memory banks to the input/output circuitry arranged on the first semiconductor chip. Accordingly, the electrically conductive connecting means each are extending from the first semiconductor chip to one respective second semiconductor chip.

According to one embodiment the electrically conductive connecting means are bond wires, each bond wire connecting the first semiconductor chip to one of the second semiconductor chips. Whereas in conventional stacked devices bond wires are used to contact semiconductor chips to support structures that do not comprise input/output circuitry for operating the memory banks, according to this embodiment the bond wires are connected to the first semiconductor chip, which comprises the input/output circuitry. Accordingly, the bond wires are connecting those portions of the memory device (the memory banks and the input/output circuitry), which, in a conventional memory product, would be arranged on the same die. In contrast thereto, according to this embodiment, the spine region provided on a separate (first) semiconductor chip is connected via bond wires to each respective memory bank.

Preferably, the first semiconductor chip has a size larger than the size of the second semiconductor chips supported by the first semiconductor chip, the first semiconductor chip comprising a chip portion laterally extending beyond the second semiconductor chips. For instance, the first semiconductor chip may laterally extend beyond at least those edges of the second semiconductor chips that are close to bond pads on the upper main surfaces of the second semiconductor chips. Accordingly, bond wires may extend from the bond pads of the upper main surfaces of the second semiconductor chips to bond pads arranged on the surface portion of the first semiconductor chip laterally extending beyond the second semiconductor chips.

Accordingly, preferably the bond wires are having first ends arranged on the chip portion of the first semiconductor chip laterally extending beyond the second semiconductor chips.

According to another preferred embodiment, the second semiconductor chips comprise through-holes extending between opposed main surfaces of the second semiconductor chips and the conductive connecting means comprise through-hole fillings filling the through-holes, the through-hole fillings also extending between the two opposed main surfaces of the respective second semiconductor chip. The through-hole fillings have a thickness essentially corresponding to the thickness of the respective second semiconductor chip.

According to this embodiment electrical contacts between the stacked first and second semiconductor chips are formed by means of through-hole fillings arranged in the bulk material of the second semiconductor chips. To this end, the through-hole fillings each extend from a first, top main surface of the respective second semiconductor chip to a second, bottom main surface of the respective second semiconductor chip. They allow an alternative technique of electrically connecting the stacked semiconductor chips to one another. This alternative technique does not require bond wires or chip portions of the first semiconductor chip laterally extending beyond the lateral dimensions of the second semiconductor chips.

Preferably, the electrically conductive connecting means further comprise bond balls or other kinds of bond pads or conductive contact structures disposed between the through-hole fillings (through-hole vias) of second semiconductor chips arranged. The bond balls serve to fill the space between two respective second semiconductor chips adjacent to one another in order to connect the through-hole filling of the upper second semiconductor chip to the through-hole filling of the respective lower second semiconductor chip (or to the top main surface of the first semiconductor chip).

Preferably, the electrically conductive connecting means comprise conductive columns extending from the main surface of the first semiconductor chip through the stacked second semiconductor chips to a top main surface of an uppermost second semiconductor chip, the conductive columns being formed of through-hole fillings and bond balls arranged on one another in alternating order. Thereby plural second semiconductor chips each comprising a set of plural through-hole fillings may be manufactured first and may then be stacked on one another without the need to form bond wires afterwards. The bond balls may be attached to bottom or top main surfaces of the respective second semiconductor chips before or during stacking the second semiconductor chips on one another (and on the first semiconductor chip).

Preferably, the conductive connecting means are electrically connecting all second semiconductor chips in parallel to the first semiconductor chip. This means that, regarding a wiring diagram for the semiconductor product according to embodiments of the invention, all electrically conductive connecting means (like a bond pad) at the upper surface of the first semiconductor chip, irrespective of its position beyond or within the lateral size of the second semiconductor chips, is connected to all second semiconductor chips of the plurality of second semiconductor chips. Any contact pad at the upper main surface of the first semiconductor chip is thus connected to the first through n-th second semiconductor chip stacked on the first semiconductor chip.

Preferably, non-conductive adhesive layers are provided between the second semiconductor chips of the plurality of second semiconductor chips as well as between the plurality of second semiconductor chips and the first semiconductor chip. The adhesive layers may be support layers since they support the stacked semiconductor chips. They can also be regarded as separation layers since they separate (and preferably electrically insulate) the second semiconductor chips from one another. The adhesive layers preferably have a thickness allowing bonding of through-hole fillings via bond balls (in case that through-hole fillings are provided in the second semiconductor chips). Consequently, there is no limitation regarding the number of second semiconductor chips stackable on one another and supported by the first semiconductor chip. Preferably, 2ⁿ second semiconductor chips are stacked on the first semiconductor chip comprising the memory bank operating circuitry.

Preferably, the through-hole fillings and the through-holes are provided in laterally centered positions within the second semiconductor chips and the bond balls are provided in recesses of the adhesive layers. This allows provision of the through-hole fillings in any desired position within the main surface of the second semiconductor chips.

Alternatively, the through-hole fillings are provided at edges of the second semiconductor chips and the bond balls are provided laterally outside of the adhesive layers. According to this embodiment, a chip stack of increased mechanical stability is achieved since the bond balls provided close to the edges of the second semiconductor chips may be used to safely fix the second and first semiconductor chips relative to one another. In this case, the adhesive layers also may be omitted, if desired.

Preferably, the semiconductor product further comprises a support substrate, the support substrate supporting the first semiconductor chip. Accordingly, the plurality of second semiconductor chips, the first semiconductor chip and the support substrate are stacked on one another. Between the first semiconductor chip and the support substrate, a similar adhesive layer or other mechanical/electrically connecting means as provided between the first and second semiconductor chips may be provided.

Preferably, the support substrate comprises two main surfaces, the first semiconductor chip being provided on a first main surface of the support plate and solder balls being provided at a second main surface of the support substrate. The solder balls serve to connect the semiconductor product according to embodiments of the invention to an external electronic device, like the printed circuit of a memory module or of a motherboard, etc.

Preferably, the support plate comprises vias extending between the first and second main surface of the support substrate, the vias being filled with conductive via fillings. By means of the conductive via fillings, the first semiconductor chip is electrically connected to the solder balls provided on the second, lower main surface of the support substrate. The first semiconductor chip may comprise through-hole fillings or via fillings of similar kind as those provided in the second semiconductor chips and in the support substrate, thereby allowing electrical connection of an integrated circuit on the first semiconductor chip's upper main surface from (comprising the memory bank operating circuitry for operating the memory banks) to the support substrate.

Preferably, the via fillings are electrically connected to the first semiconductor chip and at the second main surface of the support substrate the via fillings are electrically connected to the solder balls. The support substrate comprising the solder balls may be designed like a conventional ball grid array. However, whereas conventional ball grid arrays are supporting one single semiconductor chip, according to embodiments of the invention, the stack formed of the first chip and the plural second chips is supported by the support substrate.

Preferably, each second semiconductor chip comprises at least one memory bank each comprising a plurality of volatile memory cells accessible by read operations and write operations. Preferably, the stack of the first and the plural second semiconductor chips is a DRAM, the memory banks and the spine region (or input/output circuitry) being arranged on plural separate chips. Preferably, the memory banks are DRAM memory banks each comprising a respective plurality of volatile memory cells.

Preferably, the first semiconductor chip is designed to be operated at a first clock frequency and the second semiconductor chips are designed to be operated at a second clock frequency lower than the first clock frequency. Since the second semiconductor chips are operated at a lower clock frequency than the clock frequency of the first semiconductor chip, the bus width (that is the number of data lines for inputting and/or outputting data bits in and from the second semiconductor chips) is larger than the bus width of the first semiconductor chip. The different bus widths of the first semiconductor chip and of the second semiconductor chips are handled by multiplexor/demultiplexor circuits. The amount of storage capacity, that the number of bit storable in the semiconductor product according to embodiments of the invention is increased without the need to increase the number of input/output contacts at the support substrate, or between the support substrate and at the first semiconductor chip. Furthermore, the capacitive load and the parasitic influences of the external contact structures if the semiconductor product according to embodiments of the present invention are rather small.

Multiplexing and demultiplexing may be used for transferring signals between the first semiconductor chip (operating at the higher frequency) and the second semiconductor chips (operating at the lower frequency).

In another embodiment, a method for forming a semiconductor product is provided. A first semiconductor chip and a plurality of second semiconductor chips are provided. Each second semiconductor chip includes at least one memory bank with a plurality of memory cells. The first semiconductor chip includes input/output circuitry enabling transfer of data from the memory banks of the semiconductor product to an external electronic device and/or from an external electronic device to the memory banks of the semiconductor product. The plurality of second semiconductor chips and the first semiconductor chip are mounted on one another so as to obtain a stack of semiconductor chips. The first semiconductor chip supports the plurality of second semiconductor chips and the second semiconductor chips are stacked on one another. Each of the second semiconductor chips is electrically coupled to the first semiconductor chip, thereby enabling access to the memory banks of the second semiconductor chips by means of the input/output circuitry of the first semiconductor chip.

Preferably, the second semiconductor chips are electrically connected to the first semiconductor chip by applying bond wires to the first and second semiconductor chips. The bond wires each have first ends connected to the first semiconductor chip and second ends connected to a respective one of the second semiconductor chips.

In another embodiment, a first semiconductor chip and a plurality of second semiconductor chips are provided. Each second semiconductor chip includes at least one memory bank with a plurality of memory cells. The first semiconductor chip includes input/output circuitry that enables transfer of data from the memory banks of the semiconductor product to an external electronic device and/or from an external electronic device to the memory banks of the semiconductor product. The plurality of second semiconductor chips and the first semiconductor chip are mounted on one another so as to obtain a stack of semiconductor chips. The first semiconductor chip supporting the plurality of second semiconductor chips and the second semiconductor chips are stacked on one another. Through-holes are formed in the second semiconductor chips and filled with through-hole fillings. The through-hole fillings of the second semiconductor chips are electrically coupled to one another.

This second method embodiment provides a technique of stacking semiconductor chips on one another without the need to form bond wires afterwards.

Preferably, electrically connecting the through-hole fillings includes forming bond balls on the through-hole fillings, each bond ball, after stacking of the semiconductor chips, connecting through-hole fillings of two semiconductor chips adjacent to one another.

Preferably, the method further comprises providing a support substrate and mechanically and electrically connecting the first semiconductor chip to the support substrate. Through-hole fillings or via fillings may be formed in the first semiconductor chip for electrically connecting the input/output circuitry to the support substrate.

Preferably, a support substrate comprising solder balls and via fillings is provided, the via fillings serving to electrically connect the first semiconductor chip to the solder balls after the first semiconductor chip has been mounted on the support substrate.

Preferably, the second semiconductor chips each include exactly one memory bank with a plurality of volatile memory cells. Alternatively, each second semiconductor chip may include more (or less) than one memory bank.

### BRIEF DESCRIPTION OF THE DRAWINGS

The invention hereinbelow is described with reference to the accompanying figures.

FIG. 1 is a cross-sectional view of a semiconductor product of a first embodiment of the invention;

FIG. 2 is a cross-sectional view of a semiconductor product of a second embodiment of the invention;

FIG. 3 is a cross-sectional view of a semiconductor product of a third embodiment of the invention;

FIG. 4 is a schematical top view on a conventional semiconductor product;

FIG. 5 is a schematical top view on a semiconductor product according to the invention; and

FIG. 6 is a flow diagram of a method according to the invention.

The following list of reference symbols can be used in conjunction with the figures:
1 first semiconductor chip
1a chip portion
2; 2a . . . , 2n second semiconductor chip
3 support substrate
4 via filling
5 adhesive layer
6 through-hole filling
7 bond ball
9 semiconductor chip
10 semiconductor product
11, 12 main surfaces of first semiconductor chip
13 solder ball
15 electrically conductive connecting means
16 conductive column
18 bond wire
18a first end
18b second end
20; 20a, . . . , 20n memory bank
21, 22 main surface of second semiconductor chip
23 surface portion
25 input/output circuitry
26 delay locked loop
27 off-chip driver
28 input/output driver
30 memory cell
31, 32 main surface of support substrate
d1, d2 lateral extension
f2 first clock frequency
f2 second clock frequency
x, y lateral direction

### DETAILED DESCRIPTION OF ILLUSTRATIVE EMBODIMENTS

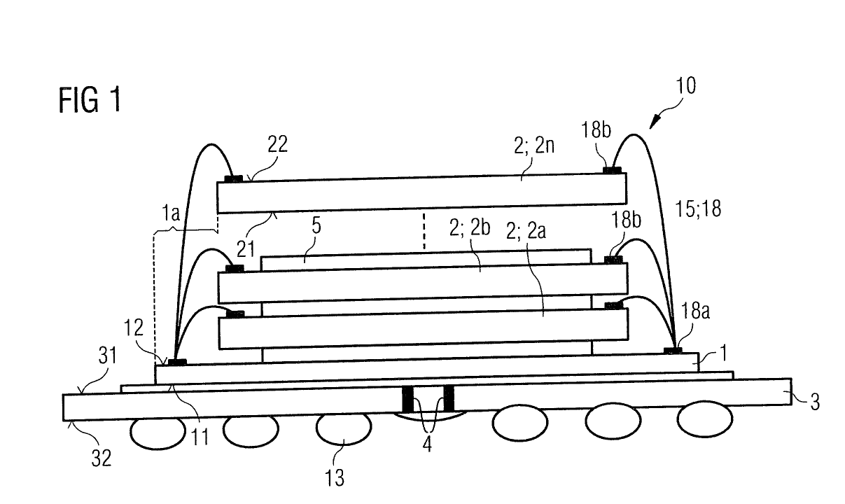

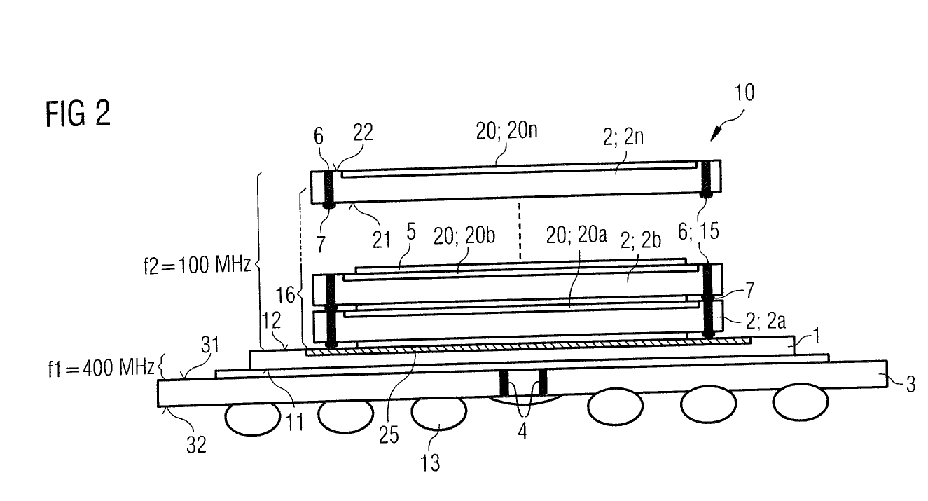

FIG. 1 illustrates a cross-sectional view of a semiconductor product of a first embodiment of the invention. The semiconductor product 10 comprises one first semiconductor chip 1 and a plurality of equally sized second semiconductor chips 2; 2a, 2b, . . . , 2n stacked on one another and being supported by the first semiconductor chip 1. For stacking the first and second semiconductor chips 1, 2 to one another, adhesive layers 5 may be provided therebetween. The second semiconductor chips 2 each comprise at least one memory bank (not illustrated in FIG. 1) which memory banks for each second memory chip may extend over almost the entire upper main surface 22 of the respective second semiconductor chip (see FIG. 2). The first and second semiconductor chips 1, 2 may be made of silicon or any other semiconductor material, for instance, and each comprise an integrated circuit. The integrated circuit of the first semiconductor chip 1 essentially is formed of a input/output circuitry which, in a conventional semiconductor chip, would be arranged in the spine region.

According to embodiments of the invention, however, the input/output circuitry is arranged on a separate, first semiconductor chip 1 and each memory bank is provided on a separate second semiconductor chip 2a, . . . , 2n. The semiconductor product 10 may further comprise a support substrate 3 supporting the first and second semiconductor chips. A further adhesive layer may be provided between the first semiconductor chip and a main surface 31 of the support substrate 3. On another main surface, contacts (like solder balls 13) are provided for communication with an external electronic device (like a printed circuit of a memory module, a motherboard, etc.). The memory device 10 comprising the support substrate 3 having the solder balls 13 may be a ball grid array (BGA). The support substrate 3 may comprise vias filled with via fillings 4 extending from a first 31 to a second main surface 32 of the support substrate 3 and thereby providing electrical connection between the first semiconductor chip 1 and the external contacts (the solder balls 13).

The first semiconductor chip 1 may laterally extend beyond the lateral size of the second semiconductor chips 2. In particular, in case of the embodiment of FIG. 1, the first semiconductor chip preferably comprises chip portions 1 a laterally extending beyond the second semiconductor chips 2 in order to facilitate electric connection between the first and second semiconductor chips. In the case of the embodiment of FIG. 1, electrical connection is achieved by means of electrically connecting means 15, which for instance comprise bond wires 18. The bond wires comprise first and second ends 18a, 18b, the first ends 18a being connected to bond pads of the first semiconductor chip 1 and the second ends 18b being connected to bond pads of respective ones of the second semiconductor chips 2. The electrically connecting means allow electrical connection of the second semiconductor chips 2a, . . . , 2n in parallel to one another to the first semiconductor chip 1. Whereas some of the second ends 18b (that is the contacts of the first semiconductor chip 1 to be connected to the second semiconductor chips 2) are connecting contacts of all second semiconductor chips in parallel to one another, other ones of the second ends 18b (that is other ones of the contacts of the first semiconductor chip 1) are connected to only one second semiconductor chip or only to a few second semiconductor chips.

FIG. 2 illustrates a cross-sectional view of a semiconductor product of the second embodiment of the present invention. According to FIG. 2, the second semiconductor chips 2 are stacked on one another and on the first semiconductor chip 1 by means of electrically conductive connecting means 15, which comprise through-hole fillings 6 and bond balls 7. Thereby no bond wires are required that would need to be provided laterally beyond the size of the second semiconductor chips 2. Each second semiconductor chip 2 comprises a plurality of through-holes that are filled with through-hole fillings 6 extending between the two respective main surfaces 21, 22 of the respective second semiconductor chip 2. The bond balls 7 are provided in spaces between two respective second semiconductor chips 2 so as to connect two through-hole fillings 6 to one another. Further elements illustrated in FIG. 2 correspond to those elements having the same reference numbers as indicated in FIG. 1.

In addition thereto, FIG. 2 schematically illustrates the memory banks 20 provided at top main surfaces 22 of the second semiconductor chips 2. The number of memory banks 20; 20a, . . . , 20n corresponds to the number of second semiconductor chips 2; 2a, . . . , 2n stacked on the first semiconductor chip 1. Accordingly, each memory bank 20 is provided on a separate second semiconductor chip 2. Furthermore, the first semiconductor chip 1 comprises the input/output circuitry 25 which, in a conventional semiconductor chip, would be arranged in the spine between all banks of the semiconductor chip. According to embodiments of the invention, however, the first semiconductor chip 1 does not comprise any memory bank of a memory array. Instead, the memory banks 20 are arranged on the second memory chips 2 only.

FIG. 2 further illustrates that the first semiconductor chip 1 is designed to be operated at a first clock frequency f1 whereas the second semiconductor chips 2 are designed to be operated at a second clock frequency f2 lower than the first clock frequency f1. For instance, the first clock frequency is, for instance, 400 MHz and the second clock frequency is, for instance, 100 MHz.

As further apparent from FIG. 2, the memory banks essentially extend over the entire top main surface 22 of the respective second semiconductor chip 2. For instance, the portion of the upper main surface covered with the memory bank 20 may be more than 85%, preferably more than 90% and more preferably more than 95% of the entire upper main surface 22. In the remaining portion of the main surface only electrical contacts to be contacted by the conductive connecting means 15 need to be arranged. In particular, no further input/output circuitry, like off-chip drivers (OCDs), for instance, is to be arranged on the respective second semiconductor chip 2.

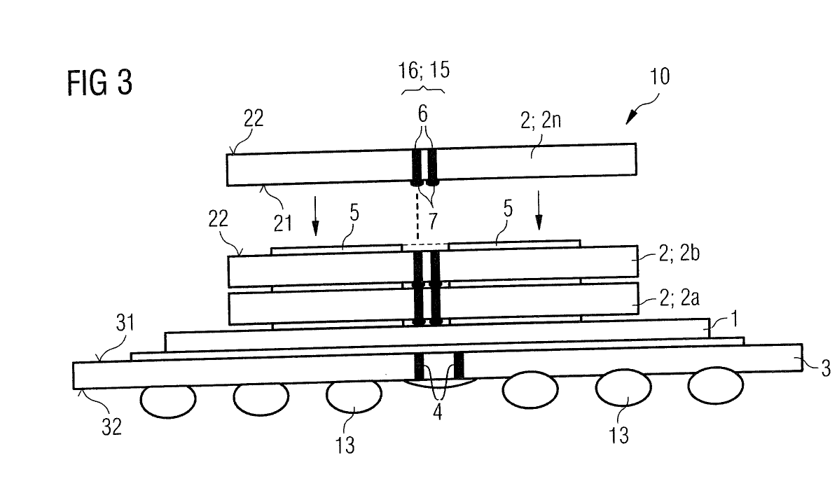

FIG. 3 illustrates a cross-sectional view of a third embodiment of the invention. According to FIG. 3, the electrically conductive connecting means are comprising through-hole fillings 6 and bond balls 7 as in FIG. 2, again conductive columns 16 formed of through-hole fillings 6 and bond balls 7 arranged on top of one another in alternating order are provided. In contrast to FIG. 2, the electrically conductive connecting means 15 in FIG. 3 are provided in laterally centered positions of the second semiconductor chips 2 rather than at the edges of the second semiconductor chips 2. In particular, the bond balls 7 are provided in recesses of the adhesive layers 5. Accordingly, the conductive columns 16 may be arranged at any desired lateral position within the lateral extensions of the second semiconductor chips 2. Further elements illustrated in FIG. 3 correspond to those elements illustrated in FIGS. 1 and 2 having the same reference numbers. The exemplary operating frequencies illustrated in FIG. 2 and the other constructional features illustrated in FIG. 2, like memory banks and input/output circuitry, for instance, are omitted in FIGS. 1 and 3 only for the sake of clearer illustration. However, they are also present in the embodiments of the FIGS. 1 and 3.

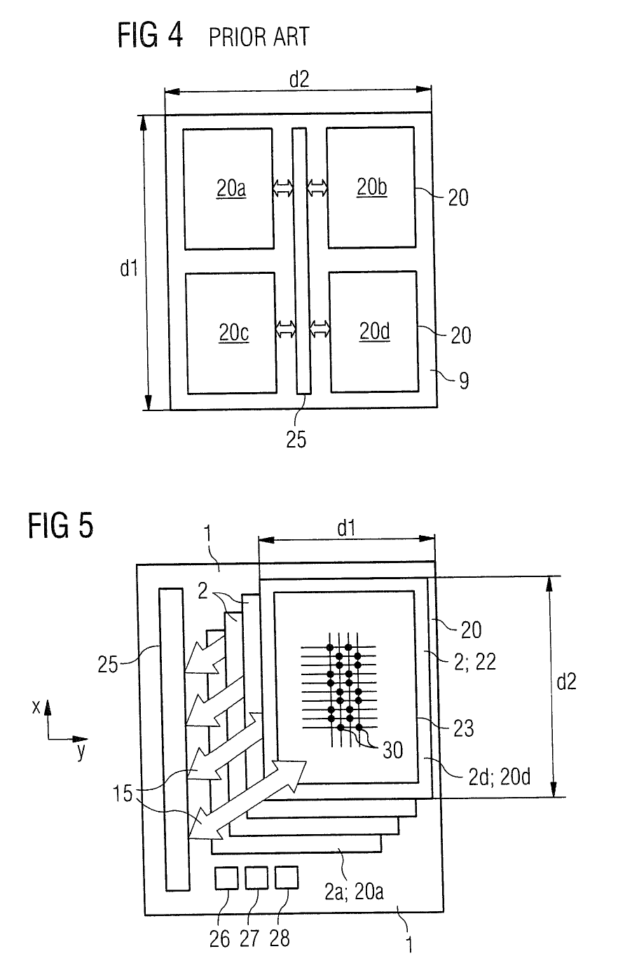

FIG. 4 illustrates a prior art semiconductor product comprising one single semiconductor chip 9. On this single die of bulk semiconductor material a plurality of memory banks 20, for instance, of four memory banks 20a, . . . , 20d is provided. In between the memory banks 20, the input/output circuitry 25 is provided for operating the memory banks 20 and for accessing the memory cells of the memory banks 20 by write operations and read operations. This conventional input/output circuitry 25 is called ‘spine’ and is integrally formed with the memory banks 20 on the same semiconductor chip 9. The semiconductor chip 9 may have the lateral extensions d1, d2, for instance. In order to increase the storage capacity of the prior art semiconductor product, the memory cells and other microelectronic devices may be shrunk and the lateral dimensions d1, d2 of the semiconductor chip 9 may be increased. However, the increase in storage capacity is only proportional to the increase of chip surface or the shrinkage of the microelectronic structures and memory cells. A further increase of a storage capacity (that is the number of bits storable) is only achieved by providing more semiconductor chips 9 like illustrated in FIG. 4, for instance by stacking them on one another. In this case, however, significantly increased load capacitances and parasitic electrical influences have to be managed when accessing all these semiconductor chips 9 in parallel. Due to these coupled parasitic influences, this kind of stacked device must be operated at a reduced clock frequency, which is disadvantageous.

FIG. 5 illustrates a schematical top view of a semiconductor product according to embodiments of the invention. The second semiconductor chips 2 stacked on one another and supported by the first semiconductor chip 1 are illustrated schematically. Conductive connecting means 15 providing electrical connection between the first semiconductor chip 1 and respective ones of the second semiconductor chips 2 are illustrated schematically by arrows. The second semiconductor chips 2 each may have the same lateral extensions d1, d2 as the semiconductor chip 9 of FIG. 4. However, each second semiconductor chip 2 comprises at least one memory bank 20 and the memory bank 20 extend entirely over nearly the whole main surface of the respective second semiconductor chip 2. The input/output circuitry 25 conventionally arranged in a spine (FIG. 4) in FIG. 5 is provided on the first semiconductor chip 1. The input/output circuitry 25 may comprise, for instance, delay locked loops (DLL) 26, off-chip-drivers 27 (OCD) and/or input/output drivers 28, schematically illustrated in FIG. 5. Accordingly, compared to FIG. 4 the storage capacity (the number of memory bits storable) of the semiconductor product of FIG. 5 is increased by a factor of four compared to the semiconductor chip 9 of FIG. 4. Furthermore, since the signals from all second semiconductor chips 2 are collected on the first semiconductor chip 1, which is operated at a higher clock frequency than the second semiconductor chips 2, the parasitic influences and the capacitive load resulting from stacking of any semiconductor chips of the semiconductor product according to embodiments of the invention are rather small compared to prior art (FIG. 4).

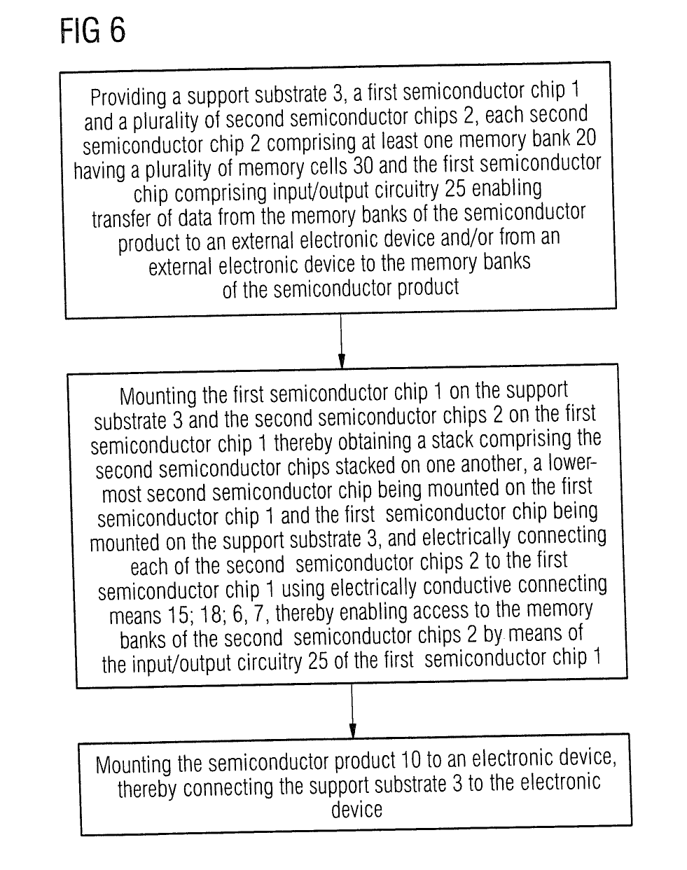

FIG. 6 illustrates an examplary flow diagram for a method according to embodiments of the invention.

Initially, a support substrate 3, a first semiconductor chip 1 and a plurality of second semiconductor chips 2 are provided, each second semiconductor chip 2 comprising at least one memory bank 20 having a plurality of memory cells 30 and the first semiconductor chip comprising input/output circuitry 25 designed for accessing memory banks by read operations and write operations. In a second step the first semiconductor chip 1 is mounted on the support substrate 3 and the second semiconductor chips 2 are mounted on the first semiconductor chip 1 and on one another, thereby obtaining a stack comprising the second semiconductor chips 2 stacked on one another, a lowermost second semiconductor chip being supported by the first semiconductor chip 1 and the first semiconductor chip being supported by the support substrate 3. Each of the second semiconductor chips 2 is electrically connected to the first semiconductor chip 1 using electrically conductive connecting means 15, 18, 6, 7, thereby enabling access to the memory banks of the second semiconductor chips by the input/output circuitry 25 of the first semiconductor chip 1. Electrically connecting can be obtained during stacking of the semiconductor chips 1, 2 or in a separate step, for instance in case of applying bond wires. Finally, the semiconductor product is mounted to an electronic device (by means of solder balls 13, for instance), thereby connecting the support substrate 3 to the electronic device, like a printed circuit board, of a memory module or any other device.

What is claimed is:

1. A semiconductor product comprising:
a first semiconductor chip, the first semiconductor chip including input/output circuitry enabling transfer of data from memory banks of the semiconductor product to an external electronic device and/or from an external electronic device to the memory banks of the semiconductor product; and
a plurality of second semiconductor chips stacked on and electrically coupled to the first semiconductor chip, the second semiconductor chips being stacked on one another, wherein each second semiconductor chip of the plurality of second semiconductor chips comprises at least one of the memory banks of the semiconductor product, the memory banks of the second semiconductor chips being accessible by the input/output circuitry arranged on the first semiconductor chip.

2. The semiconductor product of claim 1, wherein each second semiconductor chip comprises a main surface, the main surfaces of all second semiconductor chips having the same size, and wherein each memory bank of a respective second semiconductor chip covers a surface portion substantially corresponding to the main surface of the respective second semiconductor chip.

3. The semiconductor product of claim 2, wherein the at least one memory bank of the respective second semiconductor chip essentially covers the full main surface of the respective second semiconductor chip.

4. The semiconductor product of claim 3, wherein the size of the respective surface portion covered with the at least one memory bank of the respective second semiconductor chip is at least 90% of the size of the main surface of the respective second semiconductor chip.

5. The semiconductor product of claim 1, wherein the semiconductor product further comprises a connector that provides electrical connection between the first semiconductor chip and each of the second semiconductor chips.

6. The semiconductor product of claim 5, wherein the connector comprises a plurality of bond wires, each bond wire electrically connecting the first semiconductor chip to one of the second semiconductor chips.

7. The semiconductor product of claim 5, wherein the first semiconductor chip has a size larger than a size of any of the second semiconductor chips, the first semiconductor chip comprising a chip portion extending laterally beyond the second semiconductor chips.

8. The semiconductor product of claim 7, wherein the connector comprises a plurality of bond wires, the bond wires having first ends arranged on the chip portion of the first semiconductor chip extending laterally beyond the second semiconductor chips.

9. The semiconductor product of claim 5, wherein the second semiconductor chips comprise through-holes extending between two opposed main surfaces of the respective second semiconductor chip and wherein the connector comprises through-hole fillings that fill the through-holes, the through-hole fillings extending between the two opposed main surfaces of the respective second semiconductor chip.

10. The semiconductor product of claim 9, wherein the connector further comprises bond balls disposed between the through-hole fillings of the second semiconductor chip.

11. The semiconductor product of claim 10, wherein the connector comprises conductive columns extending from a main surface of the first semiconductor chip through the stacked second semiconductor chips to a top surface of an uppermost second semiconductor chip, the conductive columns being formed from through-hole fillings and bond balls arranged on one another in alternating order.

12. The semiconductor product of claim 5, wherein all second semiconductor chips are connected in parallel to the first semiconductor chip by the connector.

13. The semiconductor product of claim 5, further comprising non-conductive adhesive layers between the second semiconductor chips of the plurality of second semiconductor chips as well as between the plurality of second semiconductor chips and the first semiconductor chip.

14. The semiconductor product of claim 13:
wherein the first semiconductor chip has a size larger than a size of any of the second semiconductor chips, the first semiconductor chip comprising a chip portion extending laterally beyond the second semiconductor chips;
wherein the connector comprises a plurality of bond wires, the bond wires having first ends arranged on the chip portion of the first semiconductor chip extending laterally beyond the second semiconductor chips; and
wherein the through-holes are provided in laterally centered positions in the second semiconductor chips and wherein the bond balls are provided in recesses of the adhesive layers.

15. The semiconductor product of claim 13:
wherein the first semiconductor chip has a size larger than a size of any of the second semiconductor chips, the first semiconductor chip comprising a chip portion extending laterally beyond the second semiconductor chips;
wherein the connector comprises a plurality of bond wires, the bond wires having first ends arranged on the chip portion of the first semiconductor chip extending laterally beyond the second semiconductor chips; and
wherein the through-hole fillings are provided at edges of the second semiconductor chips and wherein the bond balls are provided laterally outside the adhesive layers.

16. The semiconductor product of claim 1, further comprising a support substrate, the support substrate supporting the first semiconductor chip.

17. The semiconductor product of claim 16, wherein the support substrate comprises first and second main surfaces, the first semiconductor chip being supported on the first main surface of the support substrate, and wherein solder balls are provided at the second main surface of the support substrate.

18. The semiconductor product of claim 17, wherein the support substrate comprises vias extending between the first and second main surfaces of the support substrate, the vias being filled with conductive via fillings.

19. The semiconductor product of claim 18, wherein the via fillings are electrically connected to the first semiconductor chip and also to the solder balls.

20. The semiconductor product of claim 1, wherein each second semiconductor chip comprises at least one memory bank comprising a plurality of non-volatile memory cells accessible by read operations and write operations.

21. The semiconductor product of claim 1, wherein the first semiconductor chip is designed to be operated at a first clock frequency and wherein the second semiconductor chips are designed to be operated at a second clock frequency lower than the first clock frequency.

22. A method for forming a semiconductor product, the method comprising the steps of:
providing a first semiconductor chip and a plurality of second semiconductor chips, each second semiconductor chip comprising at least one memory bank of memory cells, and the first semiconductor chip comprising input/output circuitry enabling transfer of data from the memory banks to an external electronic device and/or from an external electronic device to the memory banks;
mounting the plurality of second semiconductor chips and the first semiconductor chip on one another so as to obtain a stack of semiconductor chips, the first semiconductor chip supporting the plurality of second semiconductor chips and the second semiconductor chips being stacked on one another; and
electrically connecting each of the second semiconductor chips to the first semiconductor chip, thereby enabling access to the memory banks of the second semiconductor chips by the input/output circuitry of the first semiconductor chip.

23. The method of claim 22, wherein electrically connecting the second semiconductor chips to the first semiconductor chip comprises applying bond wires to the first and second semiconductor chips, the bond wires having first ends connected to the first semiconductor chip and second ends each connected to a respective one of the second semiconductor chips.

24. A method for forming a semiconductor product, the method comprising:
providing a first semiconductor chip and a plurality of second semiconductor chips, each second semiconductor chip comprising at least one memory bank comprising a plurality of memory cells, and the first semiconductor chip comprising input/output circuitry that enables transfer of data from the memory banks of the semiconductor product to an external electronic device and/or from an external electronic device to the memory banks of the semiconductor product, wherein each second semiconductor chip includes a plurality of through-holes filled with conductive through-hole fillings; and
mounting the plurality of second semiconductor chips and the first semiconductor chip on one another so as to obtain a stack of semiconductor chips, the first semiconductor chip supporting the plurality of second semiconductor chips and the second semiconductor chips being stacked on one another, wherein the mounting includes electrically connecting the through-hole fillings of the second semiconductor chips to one another.

25. The method of claim 24, wherein electrically connecting the through-hole fillings includes forming bond balls on the through-hole fillings, each bond ball connecting one respective through-hole filling of two semiconductor chips stacked on one another.

26. The method of claim 24, wherein the method further comprises providing a support substrate and mechanically and electrically connecting the first semiconductor chip to the support substrate.

27. The method of claim 26, wherein the support substrate comprises solder balls and via fillings, the via fillings serving to electrically connect the first semiconductor chip to the solder balls after the first semiconductor chip has been mounted on the support substrate.

28. The method of claim 24, wherein the at least one memory bank comprises a plurality of volatile memory cells.

29. A semiconductor product comprising:
a first semiconductor chip;
a plurality of second semiconductor chips stacked on the first semiconductor chip, the second semiconductor chips being stacked on one another, wherein each second semiconductor chip of the plurality of second semiconductor chips comprises at least one memory bank, each memory bank comprising a plurality of memory cells; and
a connector, wherein the first semiconductor chip is electrically connected to each of the second semiconductor chips by the connector;
wherein the first semiconductor chip comprises input/output circuitry that enables transfer of data from the memory banks of the semiconductor product to an external electronic device and/or from an external electronic device to the memory banks of the semiconductor product;
wherein the respective memory banks of the second semiconductor chips are accessible by the input/output circuitry arranged on the first semiconductor chip;
wherein each second semiconductor chip comprises through-holes extending between two opposed main surfaces of the respective second semiconductor chip; and
wherein the connector comprises through-hole fillings filling the through-holes of the second semiconductor chips.

30. The semiconductor product of claim 29, wherein the through-hole fillings each are extending between two opposed main surfaces of a respective second semiconductor chip.

31. The semiconductor product of claim 29, wherein the connector further comprises bond balls disposed between the through-hole fillings of the second semiconductor chip.

32. The semiconductor product of claim 31, wherein the connector comprises conductive columns extending from a main surface of the first semiconductor chip through the stacked second semiconductor chips to a top surface of an uppermost second semiconductor chip, the conductive columns being formed from through-hole fillings and bond balls arranged on one another in alternating order.

33. The semiconductor product of claim 29, wherein each second semiconductor chip comprises a main surface, the main surfaces of all second semiconductor chips having the same size, and wherein each memory bank of a respective second semiconductor chip covers a surface portion substantially corresponding to the main surface of the respective second semiconductor chip.

34. The semiconductor product of claim 29, wherein the at least one memory bank of the respective second semiconductor chip essentially covers a full main surface of the respective second semiconductor chip.

35. The semiconductor product of claim 29, wherein, for each second semiconductor chip, the at least one memory bank covers at least 90 % of the main surface of the respective second semiconductor chip.

36. The semiconductor product of claim 29, wherein the first semiconductor chip has a size larger than a size of the second semiconductor chips supported by the first semiconductor chip, the first semiconductor chip comprising a chip portion extending laterally beyond the second semiconductor chips.

37. The semiconductor product of claim 29, wherein all second semiconductor chips are electrically connected in parallel to the first semiconductor chip by the connector.

38. The semiconductor product of claim 29, further comprising non-conductive adhesive layers between the second semiconductor chips of the plurality of second semiconductor chips as well as between the plurality of second semiconductor chips and the first semiconductor chip.

39. The semiconductor product of claim 38, wherein the through-holes are provided in laterally centered positions in the second semiconductor chips and wherein the bond balls are provided in recesses of the adhesive layers.

40. The semiconductor product of claim 38, wherein the through-hole fillings are provided at edges of the second semiconductor chips and wherein the bond balls are provided laterally outside the adhesive layers.

41. The semiconductor product of claim 29, wherein the semiconductor product further comprises a support substrate, the support substrate supporting the first semiconductor chip.

42. The semiconductor product of claim 41, wherein the support substrate comprises first and second main surfaces, the first semiconductor chip being supported on the first main surface, and wherein solder balls are provided at the second main surface.

43. The semiconductor product of claim 41, wherein the support substrate comprises vias extending between the first and second main surfaces of the support substrate, the vias being filled with conductive via fillings.

44. The semiconductor product of claim 43, wherein the via fillings are electrically connected to the first semiconductor chip and are also electrically connected to solder balls on the second main surface.

45. The semiconductor product of claim 29, wherein each second semiconductor chip comprises at least one memory bank comprising a plurality of non-volatile memory cells accessible by read operations and write operations.

46. The semiconductor product of claim 29, wherein the first semiconductor chip is designed to be operated at a first clock frequency and wherein the second semiconductor chips are designed to be operated at a second clock frequency lower than the first clock frequency.
